(19) United States
(12) Patent Application Publication
(10) Pub. No.: US 2015/0349196 A1
(43) Pub. Date: Dec. 3, 2015

(54) NITRIDE SEMICONDUCTOR LIGHT-EMITTING DEVICE AND METHOD OF MANUFACTURING SAME

(71) Applicant: ILJIN LED CO., LTD., Ansan-si Gyeonggi-do (KR)

(72) Inventors: Seung-Yong KIM, Suwon-si, Gyeonggi-do (KR); Keuk KIM, Seongnam-si, Gyeonggi-do (KR)

(21) Appl. No.: 14/758,009

(22) PCT Filed: Dec. 23, 2013
(86) PCT No.: PCT/KR2013/012043

§ 371 Date: Jun. 26, 2015

(30) Foreign Application Priority Data
Dec. 28, 2012 (KR) 10-2012-0156368

(51) Int. Cl. H01L 33/00; H01L 33/42

(52) U.S. Cl. CPC H01L 33/0075; H01L 33/42; H01L 2933/0016

(57) ABSTRACT

Disclosed herein are a nitride semiconductor light-emitting device and a method of manufacturing the same, which are capable of reducing the number of masks by introducing a three-mask process so that the processing becomes simpler and the production yield can be improved.

### TECHNICAL FIELD

The present disclosure relates to a nitride semiconductor light-emitting device and a method of manufacturing the same, more specifically to a nitride semiconductor light-emitting device and a method of manufacturing the same, which are capable of reducing the number of masks by introducing a three-mask process so that the processing becomes simpler and the production yield can be improved.

### BACKGROUND ART

Among nitride semiconductor light-emitting devices, a GaN-based nitride semiconductor light-emitting device is being primarily developed. The applications of such GaN-based nitride semiconductor light-emitting devices include blue and green LEDs, high-speed switching and high-power devices such as MESFETs and HEMTs, etc.

In order to improve luminous efficiency of nitride semiconductor light-emitting devices, a current blocking pattern is formed under a p-electrode pad, along with a transparent conductive pattern covering the current blocking pattern. The transparent conductive pattern works as an electrode of the p-electrode pad and also serves to diffuse current.

However, in order to manufacture a nitride semiconductor light-emitting device having the structure, four processes using masks are required. Each of the mask processes requires a series of processes such as exposure, development, etching, etc. Accordingly, the number of mask processes increases with manufacturing costs, lowering production yield.

In the related art, Korean Patent No. 10-0793337 (published on 11 Jan. 2008) discloses a nitride semiconductor light-emitting device and a method of manufacturing the same.

### DISCLOSURE

### Technical Problem

An object of the present disclosure is to provide a nitride semiconductor light-emitting device and a method of manufacturing the same, which are capable of reducing the number of masks by introducing a three-mask process so that the processing becomes simpler and the production yield can be improved, as well as good light scattering characteristics.

### Technical Solution

An aspect of the present disclosure is to provide a nitride semiconductor light-emitting device, including: an n-type nitride layer; an active layer formed on the n-type nitride layer; a p-type nitride layer formed on the active layer; a current blocking pattern formed on the p-type nitride layer; a transparent conductive pattern covering the p-type nitride layer and the current blocking pattern and having edges with tapered cross sections symmetric to each other; and a p-electrode pad disposed at a location corresponding to a location where the current blocking pattern is located and coming in direct contact with the transparent conductive pattern.

Another aspect of the present invention is to provide a method of manufacturing a nitride semiconductor light-emitting device, the method including: (a) forming an n-type nitride layer, an active layer and a p-type nitride layer on a substrate sequentially to form a current blocking pattern on the p-type nitride layer; (b) forming a transparent conductive layer such that it covers the p-type nitride layer and the current blocking pattern to perform first patterning by selectively etching the transparent conductive layer using a mesa etch mask, to form a transparent conductive pattern; (c) performing second patterning by etching using the mesa etch mask to remove portions of the p-type nitride layer, the active layer and the n-type nitride layer exposed to one side of the substrate sequentially, to expose a part of the n-type nitride layer; and (d) forming a p-electrode pad on the transparent conductive pattern at a location corresponding to a location where the current blocking pattern is disposed, and a n-electrode pad on the exposed portion of the n-type nitride layer.

### Advantageous Effects

The nitride semiconductor light-emitting device and a method of manufacturing the same according to the exemplary embodiments of the present disclosure can reduce the number of masks by patterning the transparent conductive pattern together with the exposed portion of the n-type nitride layer disposed at an edge of the substrate using a single mask. As a result, manufacturing cost can be saved and production yield can be improved.

In addition, according to the exemplary embodiments of the present disclosure, the transparent conductive pattern is patterned at the same time of ICP mesa etching using the same mask, so that good overlay characteristics between the transparent conductive pattern and the mesa etch pattern can be achieved, and the area of the transparent conductive pattern is increased to improve luminous efficiency.

### DESCRIPTION OF DRAWINGS

FIG. 1 is a cross-sectional view of a nitride semiconductor light-emitting device according to an exemplary embodiment of the present disclosure;

FIG. 2 is an enlarged view of portion A of FIG. 1;

FIG. 3 is a flow chart illustrating a method of manufacturing a nitride semiconductor light-emitting device according to an exemplary embodiment of the present disclosure;

FIGS. 4 to 9 are cross sectional views sequentially illustrating a method of manufacturing a nitride semiconductor light-emitting device according to an exemplary embodiment of the present disclosure; and

FIG. 10 is a picture of a transparent conductive pattern after mesa etching, taken with an electron microscope.

### BEST MODE

Hereinafter, a nitride semiconductor light-emitting device and a method of manufacturing the same according to exemplary embodiments of the present disclosure will be described in detail with reference to the accompanying drawings.

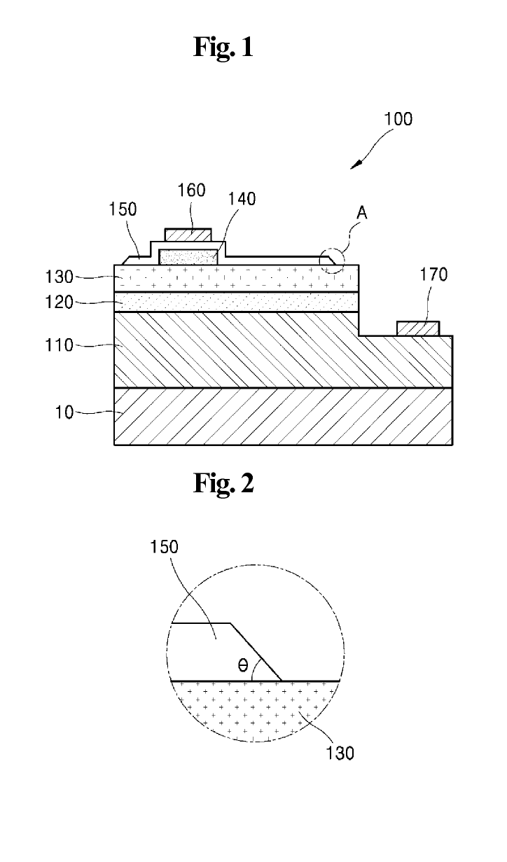

FIG. 1 is a cross-sectional view of a nitride semiconductor light-emitting device according to an exemplary embodiment of the present disclosure.

Referring to FIG. 1, the nitride semiconductor light-emitting device 100 according to the embodiment of the present disclosure includes an n-type nitride layer 110, an active layer 120, a p-type nitride layer 130, a current blocking pattern 140, a transparent conductive pattern 150, a p-electrode pad 160 and an n-electrode pad 170.

The n-type nitride layer 110 is formed on a substrate 10. The n-type nitride layer 110 may have a layered structure in which a first layer (not shown) made of AlGaN doped with silicon (Si) and a second layer (not shown) made of undoped-GaN are alternately formed. Although the n-type nitride layer may be formed as a single nitride layer, it is desirable for the n-type nitride layer to have the layered structure in which the first layer and the second layer are alternately formed with a buffer layer (not shown) therebetween, since the layered structure exhibits excellent crystallizability without cracks.

The substrate 10 may be formed of a material appropriate for growing up a nitride semiconductor single crystal. For example, the substrate 10 may be a sapphire substrate. In addition to a sapphire substrate, the substrate 10 may be formed with a material selected from zinc oxide (ZnO), gallium nitride (GaN), silicon (Si), silicon carbide (SiC), and aluminum nitride (AlN), etc. Although not shown in the drawings, the nitride semiconductor light-emitting device 100 according to the embodiment of the present disclosure may further include a buffer layer interposed between the substrate 10 and the n-type nitride layer 110. The buffer layer is optionally formed on the upper surface of the substrate 10 in order to prevent lattice mismatch between the substrate 10 and the n-type nitride layer 110. The buffer layer may be made of AlN, GaN, etc. The active layer 120 is formed on the n-type nitride layer 110. The active layer 120 may be formed between the n-type nitride layer 110 and the p-type nitride layer 130 and may have a single quantum well structure or a multi-quantum well (MQW) structure in which quantum well layers and barrier layers are alternately stacked one another . That is, the active layer 120 may have a (MQW) structure formed by the barrier layers made of quaternary nitride layers of AlGaInN containing Al and quantum well layers made of InGaN. The active layer 120 having the MQW structure is capable of suppress spontaneous polarization due to stress and deformation.

The p-type nitride layer 130 may have a layered structure in which a first layer (not shown) made of p-type AlGaN doped with magnesium (Mg) as a p-type dopant and a second layer (not shown) made of p-type GaN doped with Mg are alternately formed. Similarly to the n-type nitride layer 110, the p-type nitride layer 130 may works as a carrier blocking layer.

The current blocking pattern 140 is formed on the p-type nitride layer 130. The current blocking pattern 140 is formed at a location corresponding to a location where a p-electrode pad is to be formed (not shown).

The current blocking pattern 140 serves to compensate for optical loss due to photon absorption under the p-electrode pad 160. In addition, the current blocking pattern 140 serves to prevent current from being concentrated around the p-electrode pad 160, which happens because the p-type nitride layer 130 is thinner than the n-type nitride layer 110 so that electric conductivity is lower around the p-electrode pad 160.

Preferably, the current blocking pattern 140 is made of one or more selected from SIO2, SINx, etc. The thickness of the current blocking pattern 140 ranges preferably from 0.01 μm to 0.50 μm, more preferably 0.1 μm to 0.3 μm. If the thickness of the current blocking pattern 140 is below 0.01 μm, it is too thin to perform current blocking functionality properly. If the thickness of the current blocking pattern 140 is above 0.50 μm, it increases manufacturing cost and time unnecessarily without any substantially increase in current blocking effects, and thus is uneconomical.

The transparent conductive pattern 150 covers the p-type nitride layer 130 and the current blocking pattern 140, and has edges which have tapered cross sections symmetric to each other.

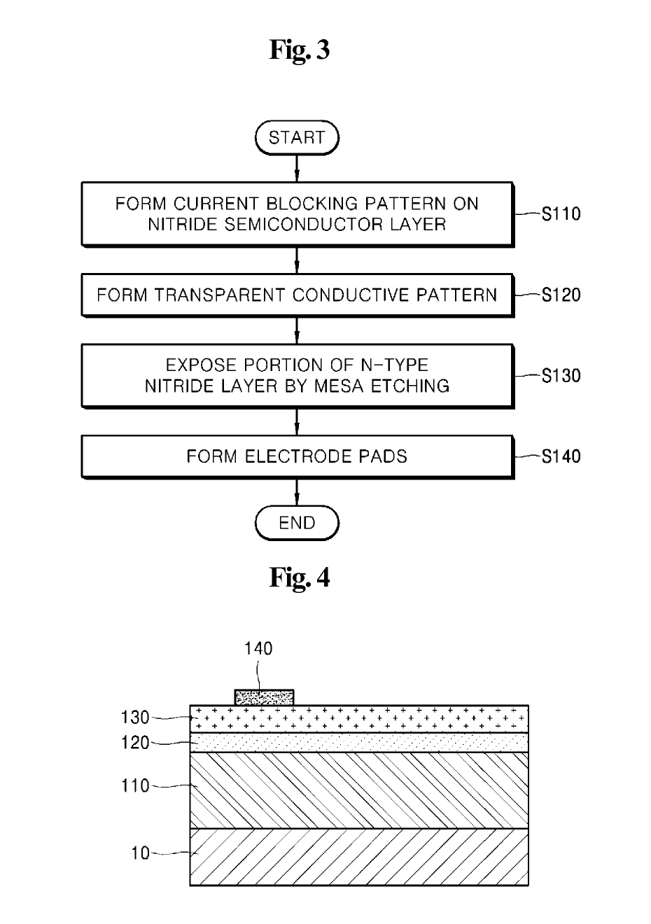

FIG. 2 is an enlarged view of portion A shown in FIG. 1. Referring to FIG. 2, tapered cross sections of the transparent conductive pattern 150 are formed during a patterning process using the same mask used for mesa etching for exposing one side of the substrate 10 (see FIG. 1), by way of overly etching a part of the transparent conductive pattern. The angle of the tapered cross sections varies from 10° to 90° depending on etching conditions. As used herein, the angle of a tapered cross section refers to the angle made by the upper surface of the substrate and the sloped surface of the tapered cross section.

Referring back to FIG. 1, the transparent conductive pattern 150 is formed to increase the area for injecting current. It is desirable to form the conductive pattern 150 with a transparent conductive material, in order not to deteriorate brightness. That is, the transparent conductive pattern 150 may be made of one or more selected from Indium Tin Oxide (ITO), Indium Zinc Oxide (IZO), FTO (fluorine doped in oxide, SnO2), etc.

The p-electrode pad 160 is disposed above the current blocking pattern 140 and comes in contact with the transparent conductive pattern 150. The p-electrode pad 160 may have a first area, and the current blocking pattern 140 may have a second area equal to or larger than the first area.

The n-electrode pad 170 is formed in an exposed portion of the n-type nitride layer 110. The p-electrode pad 160 and the n-electrode pad 170 may be formed by one selected from E-Beam deposition, thermal evaporation deposition, sputtering deposition, etc. The p-electrode pad 160 and the n-electrode pad 170 may be made of the same material using the same mask. The p-electrode pad 160 and the n-electrode pad 170 may be made of a material selected from Au, a Cr—Au alloy, etc.

The nitride semiconductor light-emitting device according to the exemplary embodiment of the present disclosure can reduce the number of masks by patterning the transparent conductive pattern together with the exposed portion of the n-type nitride layer disposed at an edge of the substrate using a single mask. As a result, manufacturing cost can be saved and production yield can be improved. By doing so, in the nitride semiconductor light-emitting device according to the exemplary embodiment of the present disclosure, the p-electrode pad comes in contact with the transparent conductive pattern which has edges having tapered cross sections symmetric to each other.

In other words, according to the exemplary embodiment of the present disclosure, the patterning process for forming the transparent conductive pattern and the mesa etching for exposing the n-type nitride layer are carried out using the same mask, the number of masks used can be reduced by one or two, compared to the related art using four or five masks. Accordingly, a series of processes such as exposure, development and etching also can be omitted as the number of masks is reduced, so that process can be simpler.

As a result, the manufacturing cost can be saved and production yield can be improved.

In addition, according to the embodiment of the present disclosure, the transparent conductive pattern is formed using the mask used in the mesa etching, achieving good overlay characteristics between the transparent conductive pattern and the mesa etch pattern.

In the related art, the transparent conductive pattern is performed using a mask and mesa etching is performed using another mask. In this manner, at least 5 μm offset is required in order to control alignment between the transparent conductive pattern and the mesa etch pattern. Further, it is difficult to control the offset between the transparent conductive pattern and the mesa etch pattern to 8 μm or less, if the undercuts of the transparent conductive pattern are also considered. In contrast, according to the embodiment of the present disclosure, the transparent conductive pattern is patterned when ICP mesa etching is performed, so that it is possible to control the undercuts of the transparent conductive pattern to 3 μm or less. By controlling the undercuts of the transparent conductive pattern to 3 μm or less, the area of the transparent conductive pattern is relatively increased and thus the light-emitting area is enlarged. As a result, luminous efficiency can be improved.

More detailed descriptions thereon will be given in describing a method of manufacturing a nitride semiconductor light-emitting device according to an exemplary embodiment of the present disclosure.

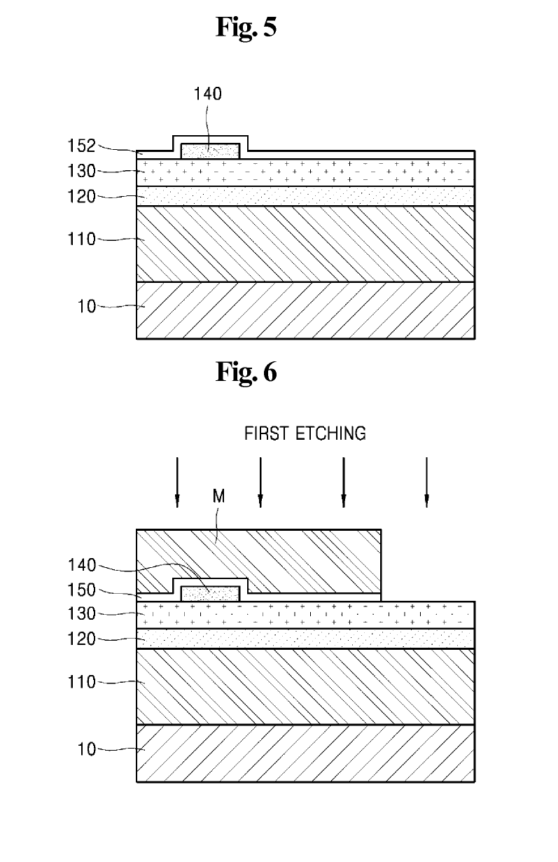

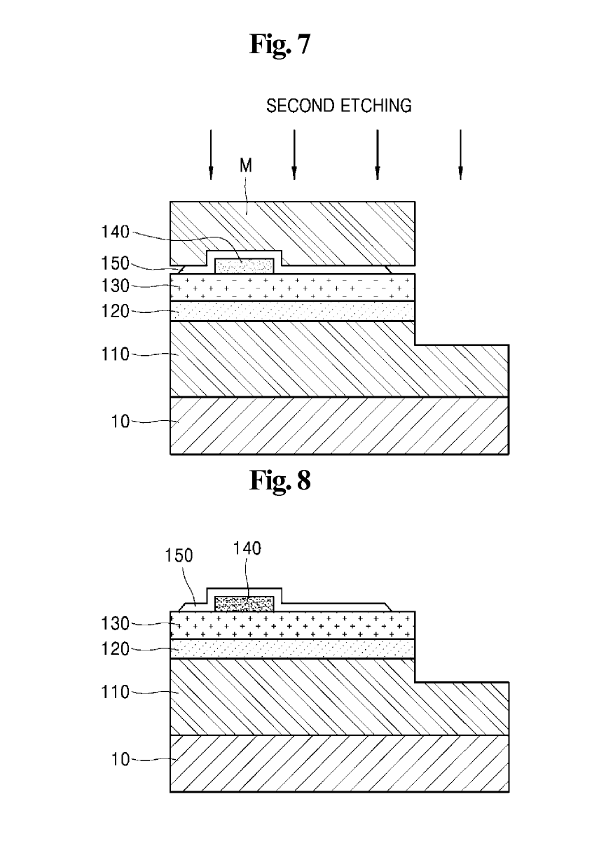

FIG. 3 is a flow chart illustrating a method of manufacturing a nitride semiconductor light-emitting device according to an exemplary embodiment of the present disclosure, and FIGS. 4 to 9 are cross sectional views sequentially illustrating a method of manufacturing a nitride semiconductor light-emitting device according to an exemplary embodiment of the present disclosure.

Referring to FIG. 3, a method of manufacturing a nitride semiconductor light-emitting device according to an exemplary embodiment of the present disclosure includes: forming a current blocking pattern on a nitride semiconductor layer (S110); forming a transparent conductive pattern (S120); performing mesa etching to expose a portion of an n-type nitride layer (S130); and forming electrode pads (S140).

Referring to FIGS. 3 and 4, in the forming the current blocking pattern on the nitride semiconductor layer (S110), an n-type nitride layer 110, an active layer 120 and a p-type nitride layer 130 are formed on a substrate 10 in this order, and then the current blocking pattern 140 is formed on the p-type nitride layer 130.

The n-type nitride layer 110, the active layer 120 and the p-type nitride layer 130 may be deposited sequentially by one selected from metalorganic chemical vapor deposition (MOCVD), liquid phase epitaxy (LPE), molecular beam epitaxy (MBE), etc.

The n-type nitride layer 110 may have a layered structure in which a first layer (not shown) made of AlGaN doped with silicon (Si) and a second layer (not shown) made of undoped-GaN are alternately formed. The active layer 120 may have a single quantum well structure or a multi-quantum well (MQW) structure in which quantum well layers and barrier layers are alternately stacked one another. The p-type nitride layer 130 may have a layered structure in which a first layer (not shown) made of p-type AlGaN doped with magnesium (Mg) as a p-type dopant and a second layer (not shown) made of p-type GaN doped with Mg are alternately formed.

Although not shown in the drawings, a buffer layer (not shown) may be further formed before the n-type nitride layer 110 is formed on the substrate 10 The buffer layer is optionally formed on the upper surface of the substrate 10 in order to prevent lattice mismatch between the substrate 10 and the n-type nitride layer 110. The made of layer may be made of AlN, GaN, etc.

The current blocking pattern 140 is formed at a location corresponding to a location where a p-electrode pad is to be formed (not shown). Although not shown in the drawings, the current blocking pattern 140 may be formed in such a manner that one or more material selected from SiO2, SiNx, etc., is deposited on the entire upper surface of the p-type nitride layer 130 at a thickness from 0.01 μm to 0.50 μm to form a current blocking material layer (not shown), and then it is subjected to a photo lithography process using a first mask (not shown). Although not shown in the drawings, the photo lithography process may be formed in such a manner that a photoresist is applied onto the entire upper surface of the p-type nitride layer 130 and the current blocking pattern 140 at a certain thickness to form a photo mask (not shown), it is selectively exposed and developed, a selective etching is performed using the photo mask, and then residual photo mask is removed using a stripping solution.

Preferably, the current blocking pattern 140 has a thickness from 0.01 μm to 0.50 μm. If the thickness of the current blocking pattern 140 is below 0.01 82 m, it is too thin to perform current blocking functionality properly. If the thickness of the current blocking pattern 140 is above 0.50 μm, it increases manufacturing cost and time unnecessarily without any substantially increase in current blocking effects, and thus is uneconomical. Referring to FIGS. 3 and 5, in the forming the transparent conductive pattern (S120), a transparent conductive layer 152 covering the p-type nitride layer 130 and the current blocking pattern 140 is formed, and then the transparent conductive layer 152 is selectively patterned using a mesa etch mask. A photoresist is applied onto a location of a transparent conductive layer 152 where the transparent conductive pattern is to be formed (not shown) and hardened. Then, selective exposure is performed so that a photoresist pattern M for the mesa etch mask is formed.

Referring to FIGS. 3 and 6, the transparent conductive pattern 150 is formed by a first patterning using the photoresist pattern M for mesa etch mask. We etching may be performed in the first patterning.

Referring to FIGS. 3 and 7, in the performing mesa etching to expose a portion of an n-type nitride layer (S130), second patterning is performed using the mesa etch mask, so that the p-type nitride layer 130, the active layer 120 and the n-type nitride layer 110 exposed to one side of the substrate 10 are sequentially removed, exposing a portion of the n-type nitride layer 110.

The second patterning using the mesa etching may be performed such that the p-type nitride layer 130, the active layer 120 and the n-type nitride layer 110 exposed from the transparent conductive pattern 150 are sequentially removed. The second patterning using the mesa etching may be performed using ICP dry etching using the transparent conductive pattern 150 at the time of the first patterning and residual photoresist pattern M on the transparent conductive pattern 150 as a mask.

After the first patterning, the transparent conductive pattern 150 has undercuts, each of which is formed by removing a part of an edge of the transparent conductive pattern 150. Accordingly, as a result of over etching in the mesa etching, the transparent conductive pattern 150 has edges with tapered cross sections symmetric to each other.

Subsequently, referring to FIG. 8, after the mesa etching, the photoresist pattern for the mesa etch mask M (see FIG. 7) covering the transparent conductive pattern 150 is removed by a stripping process.

Accordingly, in the exemplary embodiment of the present disclosure, the transparent conductive pattern 150 and the exposed portion of the n-type nitride layer 110 disposed at the side of the substrate 10 are patterned together by etching with a single mask, so that the number of masks can be reduced. As a result, production yield can be improved.

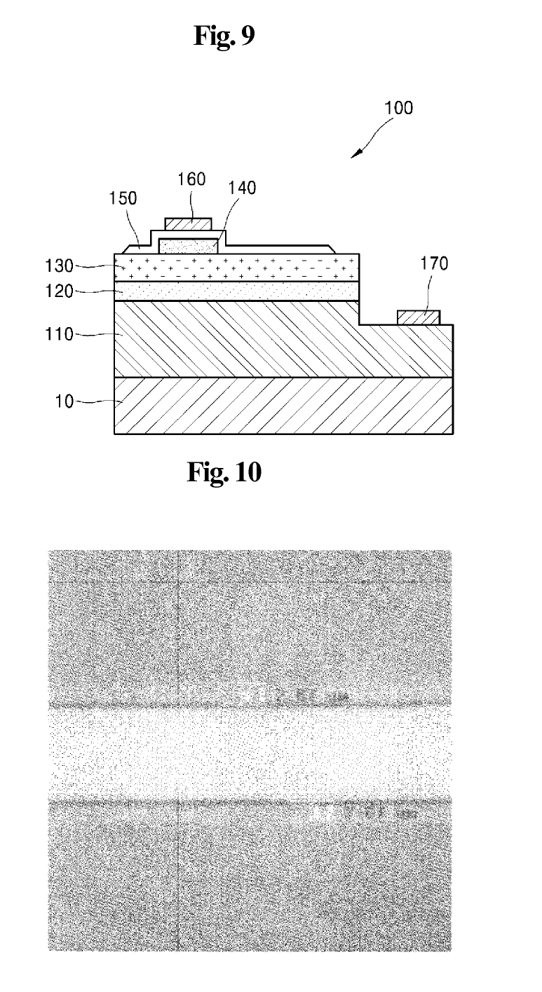

FIG. 10 is a picture of the transparent conductive pattern after the mesa etching taken with an electron microscope.

As can be seen from FIG. 10, the undercuts of the transparent conductive pattern is controlled to 2.67 μm when the transparent conductive pattern is patterned at the same time of performing ICP mesa etching. By controlling the undercuts of the transparent conductive pattern to 3 μm or less, the area of the transparent conductive pattern is relatively increased and thus the light-emitting area is enlarged. As a result, luminous efficiency can be improved.

Referring to FIGS. 3 and 9, in the forming electrode pads (S140), the p-electrode pad 160 is formed on the transparent conductive pattern 150 above the current blocking pattern 140, and the n-electrode pad 170 is formed on the exposed portion of the n-type nitride layer 110. The p-electrode pad 160 and the n-electrode pad 170 may be formed in such a manner that a selective photoresist pattern is formed on the entire upper surfaces of the p-type nitride layer 130, the transparent conductive pattern 150 and the exposed portion of the n-type nitride layer 110 by photoetching using a third mask, a metal layer (not shown) is formed on the photoresist pattern, and the metal layer and the photoresist pattern are selectively removed in a lift-off process.

The p-electrode pad 160 may have a first area when viewed from its top, and the current blocking pattern 140 may have a second area equal to or larger than the first area.

The nitride semiconductor light-emitting device manufactured through the processes S100 to S140 can reduce the number of masks by patterning the transparent conductive pattern together with the exposed portion of the n-type nitride layer disposed at an side of the substrate using a single mask. As a result, manufacturing cost can be saved and production yield can be improved.

In addition, according to the embodiment of the present disclosure, the transparent conductive pattern is formed using the mask used in the mesa etching, achieving good overlay characteristics between the transparent conductive pattern and the mesa etch pattern.

In the related art, the transparent conductive pattern is performed using a mask and mesa etching is performed using another mask. In this manner, at least 5 μm offset is required in order to control alignment between the transparent conductive pattern and the mesa etch pattern. Further, it is difficult to control the offset between the transparent conductive pattern and the mesa etch pattern to 8 μm or less, if the undercuts of the transparent conductive pattern are also considered. In contrast, according to the embodiment of the present disclosure, the transparent conductive pattern is patterned when ICP mesa etching is performed, so that it is possible to control the undercuts of the transparent conductive pattern to 3 μm or less. By controlling the undercuts of the transparent conductive pattern to 3 μm or less, the area of the transparent conductive pattern is relatively increased and thus the light-emitting area is enlarged. As a result, luminous efficiency can be improved.

In the foregoing descriptions, the nitride semiconductor light-emitting device has been described in which the n-type nitride layer, the active layer, the p-type nitride layer, the current blocking pattern, the transparent conductive pattern, the p-electrode pad and the n-electrode pad are stacked one another in this order. However, it is to be understood that this is merely illustrative and the nitride semiconductor light-emitting device may have another structure in which the n-type elements and the p-type elements are reversed.

1. A nitride semiconductor light-emitting device comprising:
an n-type nitride layer;
an active layer formed on the n-type nitride layer;
a p-type nitride layer formed on the active layer;
a current blocking pattern formed on the p-type nitride layer;
a transparent conductive pattern covering the p-type nitride layer and the current blocking pattern and having edges with tapered cross sections symmetric to each other; and
a p-electrode pad disposed at a location corresponding to a location where the current blocking pattern is located and coming in direct contact with the transparent conductive pattern.

2. The light-emitting device according to claim 1, further comprising: an n-electrode pad formed on an exposed portion of the n-type nitride layer.

3. The light-emitting device according to claim 1, wherein the current blocking pattern is made of one or more selected from SiO₂ and SiNₓ.

4. The light-emitting device according to claim 1, wherein the current blocking pattern has a thickness from 0.01 μm to 0.50 μm.

5. The light-emitting device according to claim 1, wherein the transparent conductive pattern is made of one or more selected from indium in oxide (ITO), indium zinc oxide (IZO) and fluorine doped in oxide (FTO, SnO₂).

6. The light-emitting device according to claim 1, wherein the tapered cross sections of the transparent conductive pattern have an angle between 10° and 90°.

7. The light-emitting device according to claim 1, wherein the transparent conductive pattern has undercuts, wherein each of the undercuts is formed by removing a part of either edge of the transparent conductive pattern.

8. The light-emitting device according to claim 7, wherein the undercuts of the transparent conductive pattern have a width equal to or less than 3 μm.

9. A method for manufacturing a nitride semiconductor light-emitting device, the method comprising:
(a) forming an n-type nitride layer, an active layer and a p-type nitride layer on a substrate sequentially and forming a current blocking pattern on the p-type nitride layer;
(b) forming a transparent conductive layer such that it covers the p-type nitride layer and the current blocking pattern to perform first patterning by selectively etching the transparent conductive layer using a mesa etch mask, to form a transparent conductive pattern;
(c) performing second patterning by etching using the mesa etch mask to remove portions of the p-type nitride layer, the active layer and the n-type nitride layer exposed to one side of the substrate sequentially, to expose a part of the n-type nitride layer; and
(d) forming a p-electrode pad on the transparent conductive pattern at a location corresponding to a location where the current blocking pattern is disposed, and a n-electrode pad on the exposed portion of the n-type nitride layer.

10. The method according to claim 9, wherein the (b) forming a transparent conductive layer comprises removing a part of either edges of the transparent conductive pattern such that the transparent conductive pattern has undercuts.

11. The method according to claim 10, wherein the undercuts of the transparent conductive pattern have a width equal to or less than 3 μm.

12. The method according to claim 9, wherein the (a) forming the current blocking pattern comprises forming the current blocking pattern with one or more selected from SiO₂ and SiNₓ.

13. The method according to claim 9, wherein the current blocking pattern has a thickness from 0.01 μm to 0.50 μm.

14. The method according to claim 9, wherein the first patterning uses we etching using the mesa etch mask, and the second patterning uses ICP dry etching using the same mesa etch mask as used in the first patterning, the first patterning and the second patterning being performed sequentially.

15. The method according to claim 9, wherein the transparent conductive pattern has edges with tapered cross sections symmetric to each other, after the (c) performing second patterning and before the (d) forming a p-electrode pad and an n-electrode pad.

16. The method according to claim 15, wherein the tapered cross sections of the transparent conductive pattern have an angle between 10° and 90°.
